(19) United States
(12) Patent Application Publication
(10) Pub. No.: US 2004/0244688 A1
(43) Pub. Date: Dec. 9, 2004

(54) Plasma processing apparatus

(75) Inventors: Shinji Himori, Nirasaki-shi (JP); Itsuko Sakai, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Minato-ku (JP); KABUSHIKI KAISHA TOSHIBA, Tokyo (JP)

(21) Appl. No.: 10/810,694

(22) Filed: Mar. 29, 2004

Related U.S. Application Data
(63) Continuation of application No. PCT/JP02/09999, filed on Sep. 27, 2002.

(30) Foreign Application Priority Data
Sep. 28, 2001 (JP) P2001-303714

(51) Int. Cl. C23C 16/00

(52) U.S. Cl. 118/723 E

(57) ABSTRACT

A HF matching device 14 and a LF matching device 17 are separately structured, the HF matching device 14 being configured such that it is disposed at a center portion on a lower side of a bottom electrode 2 so as to be positioned in a space 13 provided on the lower side of the bottom electrode 2 and an output side thereof is electrically connected to the bottom electrode 2 via a non-coaxially structured feeding rod 19 (not via a coaxially-structured feeding rod). A radio-frequency power from a second radio-frequency power source 18 is supplied from an outer peripheral portion of the bottom electrode 2 via the LF matching device 17 and a LPF 16. This configuration makes it possible to suppress the increase in power loss even when a radio-frequency power with a high frequency is used and to facilitate matching without using any special matching element.

### TECHNICAL FIELD

The present invention relates to a plasma processing apparatus, more particularly, to a plasma processing apparatus that applies plasma processing such as etching and deposition on a substrate to be processed such as a semiconductor wafer or a glass substrate for LCD.

### BACKGROUND ART

In a semiconductor device manufacturing field, such a plasma processing apparatus have been conventionally used, that performs predetermined processing (for example, etching, deposition, or the like) by generating plasma in a process chamber and having this plasma act on a substrate to be processed (for example, a semiconductor wafer, a glass substrate for LCD, or the like) disposed in the process chamber. In such a plasma processing apparatus, the application of the predetermined processing on the substrate to be processed by the action of plasma is conducted in a vacuum chamber, the inside of which can be airtightly closed. In a plasma processing apparatus of, for example, a so-called parallel-plate electrode type, a top electrode and a bottom electrode are provided in this vacuum chamber, facing and being parallel to each other. The predetermined processing is applied in such a manner that the substrate to be processed is placed on the bottom electrode, a radio-frequency power is supplied between the top electrode and the bottom electrode to generate plasma of processing gas, and the plasma is made to act on the substrate to be processed.

Further, in recent years, a plasma processing apparatus having a configuration as shown in FIG. 5 has also been developed in order to separately control plasma density and ion energy acting on a substrate to be processed. In the plasma processing apparatus shown in FIG. 5, a bottom electrode 100 is supplied with a radio-frequency power with a high frequency from a first radio-frequency power source 101 while being supplied with a radio-frequency power with a frequency lower than this frequency from a second radio-frequency power source 102, so that two kinds of radio-frequency powers with different frequencies are superimposed to be supplied to the bottom electrode 100.

Thus, in such a plasma processing apparatus, the radio-frequency power with the high frequency is supplied to increase plasma density and the radio-frequency power with the lower frequency is supplied so that ion energy at the time of the introduction of ions in the plasma into the substrate to be processed is controlled to be low.

As shown in FIG. 5, a focus ring 103 made of quartz or the like is provided surrounding the bottom electrode 100, and an insulator plate 105 is provided on a lower portion of the bottom electrode 100, for electrical insulation from a vacuum chamber bottom portion 104.

Under the bottom electrode 100, further provided are a wafer lift mechanism 107 for lifting a wafer or the like as the substrate to be processed to a position above the bottom electrode 100 by a plurality of (typically three or four) lifter pins 106 or the like, and components 108 such as a pipe system through which a cooling solvent for cooling is to be supplied to the bottom electrode 100, a pipe system through which gas (for example, He gas) for heat conduction is to be supplied between a wafer rear face and the bottom electrode 100, and cables of an electric system for a temperature sensor and an electrostatic chuck.

A matching device 110 for impedance matching is large in its outer shape since it is constituted of a HF matching portion 111 for impedance matching for the radio-frequency power with the high frequency supplied from the first radio-frequency power source 101, a LF matching portion 112 for impedance matching for the. radio-frequency power with the lower frequency supplied from the second radio-frequency power source 102, a LPF (low pass filter) 113, and so on.

As a result, it is difficult to dispose the matching device 110 near the bottom electrode 100, and therefore, the supply of the radio-frequency power, in which the radio-frequency powers with two frequencies are superimposed, to the bottom electrode 100 is realized by such a configuration that the matching device 110 and the bottom electrode 100 are electrically connected to each other by a coaxially structured feeding rod 120 whose length is set to several tens cm (for example, about 50 cm).

As described above, in the conventional plasma-processing apparatus, the matching device is provided outside the vacuum chamber, and the matching device and the bottom electrode are electrically connected to each other by the feeding rod that is, for example, about 50 cm in length.

However, as the aforesaid radio-frequency power, a radio-frequency power with a frequency of several tens MHz to several hundreds MHZ, which is higher than the conventionally used frequency, is coming into use in recent years.

This has posed the aforesaid conventional plasma processing apparatus such problems that L (inductance) and C (capacitance) components in the feeding rod cause increase in power loss to generate heat and to result in a high voltage. Moreover, such a problem arises at the time of matching in the matching device that, if a commercially available matching element (vacuum variable capacitor or the like) is used, a required small C (capacitance) cannot be obtained, which makes matching difficult.

### DISCLOSURE OF THE INVENTION

Therefore, it is an object of the present invention to provide a plasma processing apparatus capable of suppressing increase in power loss even when a radio-frequency power with a high frequency is used and capable of easily realizing matching without using any special matching element.

A plasma processing apparatus according to one of the aspects of the present invention is characterized in that it includes: a vacuum chamber in which predetermined processing is to be applied on a substrate to be processed by action of plasma on the substrate to be processed, inside of the vacuum chamber being airtiqhtly closable; a bottom electrode provided in the vacuum chamber and configured to have the substrate to be processed placed thereon; a top electrode provided to face the bottom electrode; a processing gas supply mechanism configured to supply predetermined processing gas into the vacuum chamber; a first radio-frequency power source configured to supply a radio-frequency power with a predetermined first frequency to the bottom electrode; a second radio-frequency power source configured to supply to said bottom electrode a radio-frequency power with a second frequency that is lower than the first frequency; a first power feeder having a first matching device that performs impedance matching for the radio-frequency power to be supplied to the bottom electrode from the first radio-frequency power source, the first power feeder being configured to feed the radio-frequency power with the first frequency to the bottom electrode from a center portion of the bottom electrode; and a second power feeder having a second matching device that is structured as a separate body from the first matching device and performs impedance matching for the radio-frequency power to be supplied to the bottom electrode from the second radio-frequency power source, the second power feeder being configured to feed the radio-frequency power with the second frequency to the bottom electrode from an outer peripheral portion of the bottom electrode.

A plasma processing apparatus according to another aspect of the present invention is characterized in that the bottom electrode is supported on an insulator plate formed in a plate shape, and a space is formed between the insulator plate and a bottom portion of the vacuum chamber that is set to a ground potential.

A plasma processing apparatus according to still another aspect of the present invention is characterized in that the first matching device is disposed in the space.

A plasma processing apparatus according to yet another aspect of the present invention is characterized in that the first matching device is electrically connected to the bottom electrode via a non-coaxially structured feeding rod.

A plasma processing apparatus according to yet another aspect of the present invention is characterized in that the first frequency is 13.56 MHz to 150 MHz.

A plasma processing apparatus according to yet another aspect of the present invention is characterized in that the second frequency is 0.5 MHz to 13.56 MHz.

A plasma processing apparatus according to yet another aspect of the present invention is characterized in that capacitance of the bottom electrode is set to 50 pF or less.

A plasma processing apparatus according to yet another aspect of the present invention is characterized in that the substrate to be processed is etched by the action of the plasma on the substrate to be processed.

### BRIEF DESCRIPTION OF DRAWINGS

FIG. 1 is a view schematically showing the rough configuration of a first embodiment of a plasma processing apparatus of the present invention.

FIG. 2 is a view schematically showing the structure of an essential portion of the plasma processing apparatus in FIG. 1.

FIG. 3 is a view schematically showing a modification example of the structure of the essential portion of the plasma processing apparatus in FIG. 1.

FIG. 4 is a chart showing the correlation between the material and thickness of an insulting portion on a lower side of a bottom electrode and total capacitance.

FIG. 5 is a view schematically showing the rough configuration of an essential portion of a conventional plasma processing apparatus.

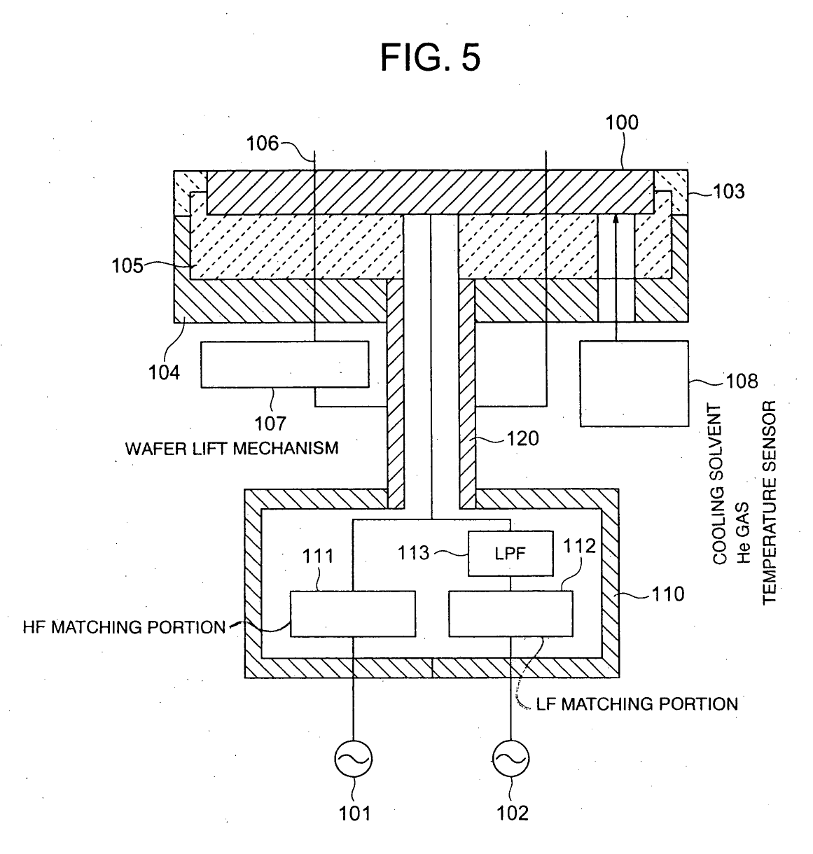

### BEST MODE FOR IMPLEMENTING THE INVENTION

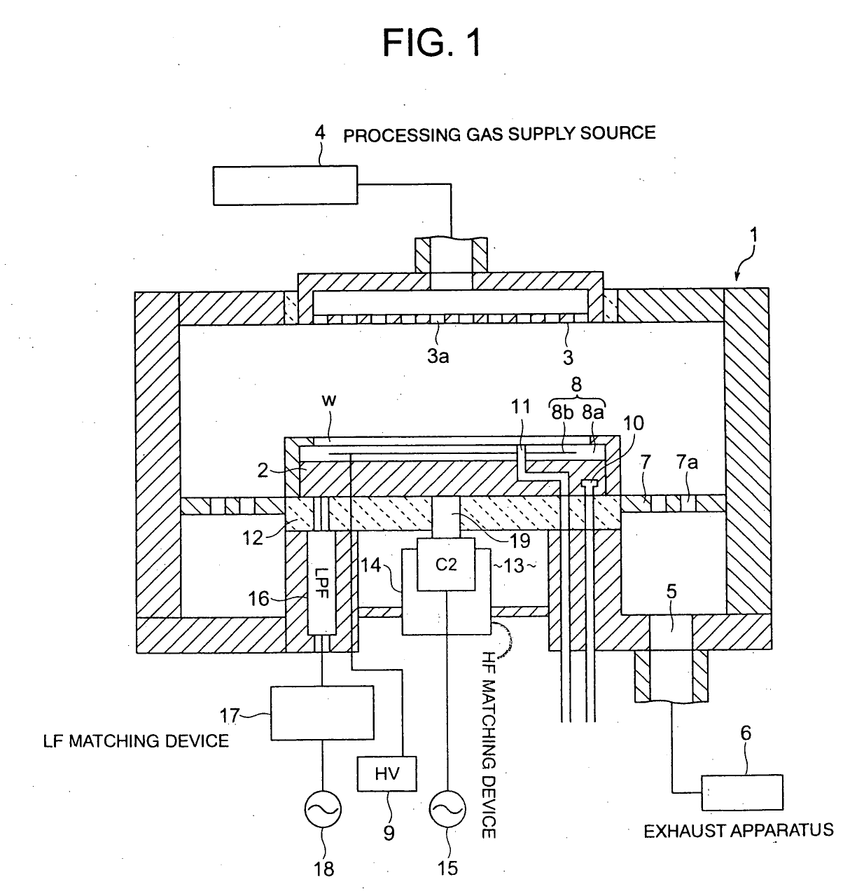

Hereinafter, the present invention will be detailed by describing an embodiment with reference to the drawings. FIG. 1 schematically shows the rough configuration of an embodiment in which the present invention is applied to a plasma etching apparatus that etches wafers. In the drawing, the reference numeral 1 denotes a vacuum chamber made of, for example, aluminum or the like, the inside of the vacuum chamber being configured to be airtightly closable and serving as a cylindrical plasma process chamber.

A bottom electrode 2 is provided inside the vacuum chamber 1, the bottom electrode 2 being configured to hold a wafer (semiconductor wafer) W as a substrate to be processed substantially horizontal with a surface to be processed of the wafer W facing upward. Further, a top electrode 3 is provided on a ceiling portion inside the vacuum chamber 1 to be parallel to and face the bottom electrode 2.

The top electrode 3 has a large number of through holes 3a formed therein to form a so-called showerhead. These through holes 3a are configured to be capable of uniformly sending therethrough predetermined processing gas supplied form a processing gas supply source 4 to the wafer W placed on the bottom electrode 2.

An exhaust port 5 is provided in a bottom portion of the vacuum chamber 1, being positioned outside the outer periphery of the bottom electrode 2, and this exhaust port 5 is connected to an exhaust apparatus 6 constituted of a vacuum pump or the like.

Further, an exhaust ring (baffle plate) 7 made of a ring-shaped plate member is provided around the bottom electrode 2 at a position lower than a mounting face, being interposed between the outer peripheral portion of the bottom electrode 2 and an inner wall portion of the vacuum chamber 1. This exhaust ring 7 has a large number of through holes 7a formed therein.

Exhausting from the exhaust port 5 by the exhaust apparatus 6 via this exhaust ring 7 realizes uniform exhaust from an area surrounding the bottom electrode 2 to form a uniform flow of the processing gas in the vacuum chamber 1.

Further, an electrostatic chuck 8 to electrostatically hold the wafer W by suction is provided on an upper face of the bottom electrode 2. This electrostatic chuck 8 is constituted of insulators 8a and an electrode 8b disposed between the insulators Ba, and a direct-current high-voltage power source (HV) 9 is connected to the electrode 8b. The application of a direct-current voltage to the electrode 8b from the direct-current high-voltage power source 9 causes the wafer W to be suction-held on the bottom electrode 2 by a Coulomb force or the like.

Further, a refrigerant flow path 10 to circulate a refrigerant and a gas introducing mechanism 11 to supply He gas to a rear face of the wafer W for efficient conduction of cool heat from the refrigerant to the wafer W are provided in the bottom electrode 2, so that the temperature of the wafer W can be controlled to a desired temperature. Pipes or the like for supplying the refrigerant and the He gas to these refrigerant flow path 10 and gas introducing mechanism 11 from the outside are provided to be positioned at the outer peripheral portion of the bottom electrode 2.

Moreover, an insulator plate 12 made of an insulting material, for example, alumina or the like is provided on a lower side of the bottom electrode 2, so that the bottom electrode 2 is supported on the bottom portion of the vacuum chamber 1 via this insulator plate 12. Note that the vacuum chamber 1 is set to a ground potential.

A space 13 is formed between a lower portion of the insulator plate 12 and the bottom portion of the vacuum chamber 1, and a HF matching device 14 is provided in this space 13 at a center portion of the bottom electrode 2.

This HF matching device 14 is electrically connected to the center portion of the bottom electrode 2 at an electrical output-side end portion thereof and an input side thereof is connected to a first radio-frequency power source 15. A first power feeder is configured to enable the supply of a radio-frequency power (with a frequency of 13.56 MHz to 150 MHz, for example, 100 MHz) from the first radio-frequency power source 15 to the center portion of the bottom electrode 2 via the HF matching device 14.

A variable capacitor C2, which is inserted in series in a power feeding circuit, for impedance matching is provided at the output-side end portion of the HF matching device 14. In this embodiment, a vacuum variable capacitor constitutes this capacitor C2. This capacitor C2 is electrically connected to the bottom electrode 2 by a non-coaxially structured feeding rod 19. Here, the non-coaxially structured feeding rod means a single cylindrical feeding rod or a feeding rod constituted of a single conductor in a shape other than a cylindrical shape, with no ground conductor on an outer side thereof, as shown in FIG. 1. Further, the reason why the use of a coaxially structured feeding rode is not required in this embodiment is that a grounded chamber wall functions as the outer side ground conductor of the coaxially structured feeding rod owing to its short feeding path, so that a sufficient shielding effect is obtainable. Further, in this case, the coaxially structured feeding rod may also be used in order to enhance the shielding effect thereof.

Moreover, a LPF (low pass filter) 16 for filtering out the radio frequency supplied from the aforesaid first radio-frequency power source 15 is provided on a lower side of the outer peripheral portion of the bottom electrode 2, and the second radio-frequency power source 18 is electrically connected to the outer peripheral portion of the bottom electrode 2 via this LPF 16 and a LF matching device 17. A second feeder is configured so as to enable the supply of the radio-frequency power (with a frequency of 0.5 MHz to 13.56 MHz, for example, 3.2 MHz) from the second radio-frequency power source 18 to the outer peripheral portion of the bottom electrode 2 via the LF matching device 17 and the LPF 16. Note that the electrical connection between the LPF 16 and the LF matching device 17 is realized by a coaxial pipe or a coaxial cable.

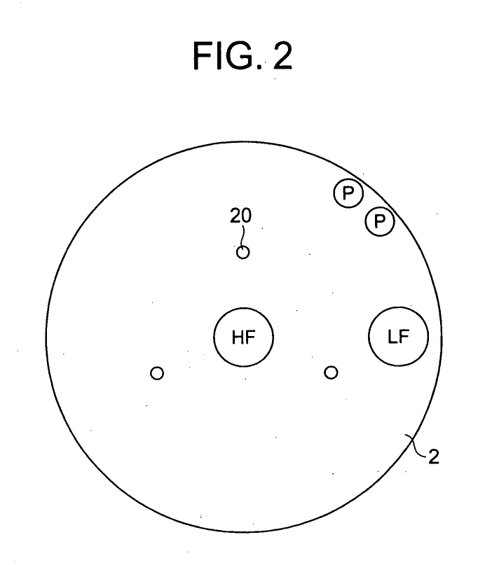

Note that a plurality of (three in this embodiment) lifter pins 20, though omitted in FIG. 1, are provided in the bottom electrode 2 to pass through the bottom electrode 2, as shown in FIG. 2. The lifter pins 20 are structured to be moved vertically by a not-shown wafer lift mechanism to support the wafer W at a position above the bottom electrode 2 when the wafer W is carried in and out.

In FIG. 2, HF denotes a portion at which the bottom electrode 2 is connected to the aforesaid matching device 14, namely, a portion from which the radio-frequency power with the first frequency is fed, LF denotes a portion at which the bottom electrode 2 is connected to the aforesaid LPF 16, namely, a portion from which the radio-frequency power with the second frequency is fed, and P denotes portions where the pipes for supplying the refrigerant and the He gas to the aforesaid refrigerant flow path 10 and gas introducing mechanism 11 from the outside and other components are provided.

As described above, in this embodiment, the HF matching device 14 and the LF matching device 17 are structured separately to realize the downsizing of the respective matching devices compared with the case where they are integrally structured.

This downsized HF matching device 14 is disposed at a center portion of the lower side of the bottom electrode 2, and the HF matching device 14 is structured to be electrically connected to the bottom electrode 2 without any coaxially structured feeding rod interposed therebetween. This makes it possible to be free from an L (inductance) component and a C (capacitance) component generated by the use of the coaxially structured feeding rod. Therefore, the occurrence of power loss can be suppressed even if a radio-frequency power with a high frequency of, for example, 60 MHz or higher is supplied from the first radio-frequency power source 15. In addition, it can be prevented that a value of C (capacitance) necessary for the capacitor C2 or the like of the HF matching device 14 becomes extremely small, so that a commercially available matching element such as a vacuum variable capacitor is usable as the capacitor C2 or the like.

Further, the radio-frequency power with the high frequency (short wavelength) from the first radio-frequency power source 15 is supplied from the center portion of the bottom electrode 2, so that uneven processing to the wafer W on the bottom electrode due to the influence of a standing wave or the like can be prevented.

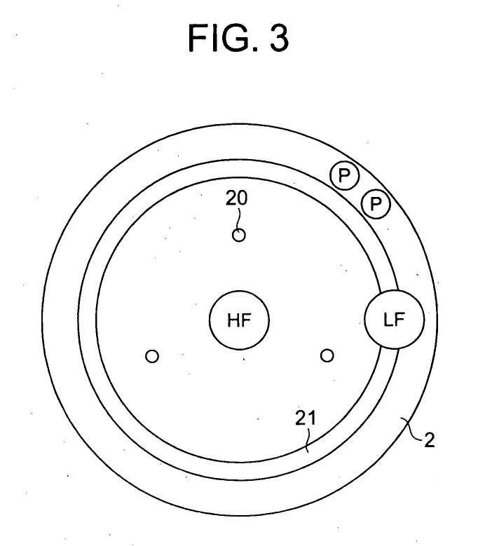

Note that, though the radio-frequency power from the second radio-frequency power source 18 is supplied from the outer peripheral portion of the bottom electrode 2, the influence of the standing wave or the like is negligible even with the adoption of this configuration since the radio-frequency power from the second radio-frequency power source 18 has a lower frequency (longer wavelength) than that of the radio-frequency power from the first radio-frequency power source 15. Alternatively, the supply portion of the radio-frequency power from the second radio-frequency power source 18 may also be configured to be connected to the bottom electrode 2 via, for example, a ring-shaped conductor (for example, aluminum or the like) 21 extending from a portion to-which the LF power is fed, as shown in FIG. 3. Such coaxial supply of the radio-frequency power to the bottom electrode 2 enables more detailed plasma control while the influence of the standing wave is being suppressed.

Further, in this embodiment, the insulator plate 12 made of an insulating material such as alumina is provided on the lower side of the bottom electrode 2, and the space 13 is formed between the lower portion of the insulator plate 12 and the bottom portion of the vacuum chamber 1, as previously described. Here, in the above configuration, C (capacitance) is formed between the bottom electrode 2 and the bottom portion (ground potential) of the vacuum chamber 1 with the insulator plate 12 and the space 13 interposed therebetween. However, the space 13 is formed in this embodiment as described above, so that the C (capacitance) component can be reduced.

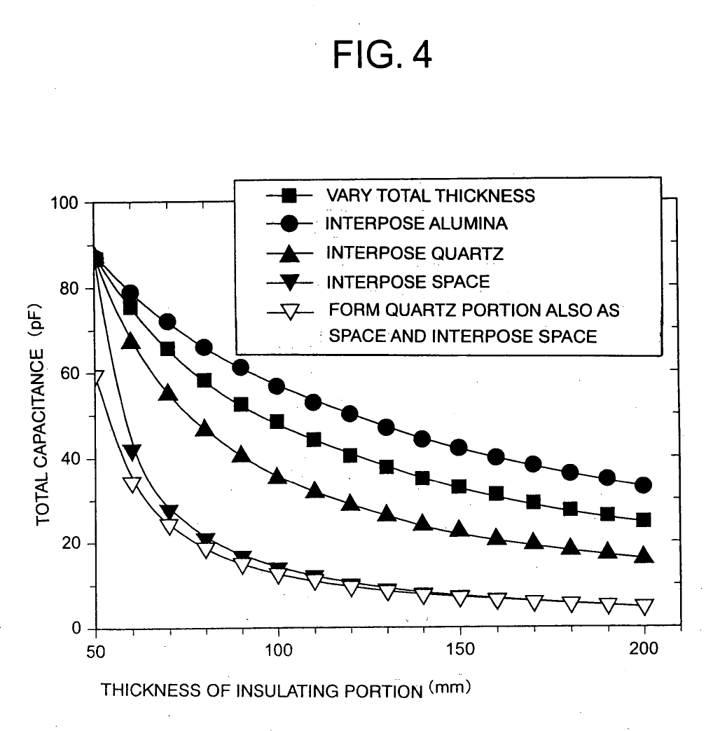

FIG. 4 shows how total capacitance varies in accordance with the variation of the thickness of the aforesaid insulating portion on the lower side of the bottom electrode 2 (distance between a lower face of the bottom electrode 2 and a bottom face of the vacuum chamber 1), the vertical axis representing total capacitance (pF) and the horizontal axis representing the thickness (mm).

In the drawing, “vary total thickness” shown by the square mark signifies that an alumina plate and a quartz plate are disposed on the lower side of the bottom electrode 2 and the thicknesses thereof are varied at the same ratio. Further, “interpose alumina” shown by the circle mark signifies that an alumina plate is interposed on the lower side of the structure in which the above-mentioned alumina plate and quartz plate are disposed and the thickness of this alumina plate is varied. Further, “interpose quartz” shown by the triangle mark signifies that quartz is interposed instead of the above-mentioned alumina and the thickness of the quartz is varied, and “interpose space” shown by the black inverted-triangle mark signifies that a space is provided instead of interposing the above-mentioned alumina and the thickness of this space is varied.

Moreover, “form quartz portion also as space and interpose space” shown by the outline inverted-triangle mark signifies that the quartz plate portion disposed on the lower side of the above-mentioned alumina plate is also formed as a space and the thickness of the space on the lower side is varied. As shown in the drawing, total capacitance can be reduced under the same thickness when the space is provided compared with the case where the alumina plate and the quartz plate are disposed.

Note that the total capacitance of the bottom electrode 2 is preferably set to about 50 pF or less, and in this embodiment, the space 13 is formed as described above to realize the capacitance of about 35 pF for the bottom electrode 2.

As is described above, in this embodiment, the total C (capacitance) component of the bottom electrode 2 can be also reduced, so that the occurrence of power loss can be suppressed even when the radio-frequency power with a high frequency of, for example, 100 MHz or higher is supplied from the first radio-frequency power source 15.

Next, a plasma etching process in the plasma etching apparatus thus configured will be explained.

First, a not-shown gate valve provided in the vacuum chamber 1 is opened. Then, the wafer W is carried into the vacuum chamber 1 by a carrier arm or the like of an automatic transfer mechanism via a not-shown load lock chamber disposed adjacent to this gate valve, and is placed on the bottom electrode 2 to be suction-held by the electrostatic chuck 8. After the wafer W is placed, the carrier arm retreats outside the vacuum chamber 1 and the gate valve is closed.

Thereafter, an exhaust mechanism 6 exhausts the inside of the vacuum chamber I while predetermined processing gas, for example, C₄F₆+Ar+O₂ (the flow rate is, for example, 45/750/30 sccm) is introduced into the vacuum chamber 1 from the processing gas supply source 4 via the through holes 3a of the top electrode 3, and the inside of the vacuum chamber 1 is kept at a predetermined pressure, for example, 5.32 Pa (40 mTorr).

Then, in this state, the radio-frequency power with a frequency of about 13.56 MHz to about 150 MHz, for example, 80 MHz is supplied to the center portion of the bottom electrode 2 from the first radio-frequency power source 15 via the aforesaid first power feeder. At the same time, the radio-frequency power with a frequency of 0.5 MHz to 13.45 MHz, for example, 3.2 MHz is supplied to the outer peripheral portion of the bottom electrode 2 from the second radio-frequency power source.18 via the aforesaid second power feeder. The application of these radio-frequency powers plasmatizes the processing gas supplied into the vacuum chamber 1 and ions in this plasma are introduced onto the wafer W on the bottom electrode 2, so that a predetermine film on the wafer W is etched.

After the film is thus etched to a desired film thickness, the supply of the radio-frequency powers from the first radio-frequency power source 15 and the second radio-frequency power source 18 and the supply of the processing gas from the processing gas supply source 4 are stopped to finish the etching process. Then, through reverse procedure from the above-described procedure, the wafer W is carried out of the vacuum chamber 1.

Incidentally, the case where the present invention is applied to the etching apparatus for etching the wafer W is explained in the above-described embodiment, but the present invention is not to be limited to such an case. The present invention is applicable to, for example, a case where a substrate other than the wafer W is processed and to a deposition apparatus for plasma processing other than etching, for example, CVD and so on.

As is explained hitherto, according to the present invention, the increase in power loss can be suppressed even when a radio-frequency power with a high frequency is used, and matching can be facilitated without using any special matching element.

Industrial Applicability

A plasma processing apparatus according to the present invention is usable in the semiconductor manufacturing industry and the like where semiconductor devices are manufactured. Therefore, the present invention has industrial applicability.

1. A plasma processing apparatus comprising:
a vacuum chamber in which predetermined processing is to be applied on a substrate to be processed by action of plasma on the substrate to be processed, inside of the vacuum chamber being airtightly closable;
a bottom electrode provided in said vacuum chamber and configured to have the substrate to be processed placed thereon;
a top electrode provided to face said bottom electrode;
a processing gas supply mechanism configured to supply predetermined processing gas into said vacuum chamber;
a first radio-frequency power source configured to supply a radio-frequency power with a predetermined first frequency to said bottom electrode;
a second radio-frequency power source configured to supply to said bottom electrode a radio-frequency power with a second frequency that is lower than the first frequency;
a first power feeder having a first matching device that performs impedance matching for the radio-frequency power to be supplied to said bottom electrode from said first radio-frequency power source, said first power feeder being configured to feed the radio-frequency power with the first frequency to said bottom electrode from a center portion of said bottom electrode; and
a second power feeder having a second matching device that is structured as a separate body from said first matching device and performs impedance matching for the radio-frequency power to be supplied to said bottom electrode from said second radio-frequency power source, said second power feeder being configured to feed the radio-frequency power with the second frequency to said bottom electrode from an outer peripheral portion of said bottom electrode.

2. A plasma processing apparatus as set forth in claim 1,
wherein said bottom electrode is supported on an insulator plate formed in a plate shape, and a space is formed between the insulator plate and a bottom portion of said vacuum chamber that is set to a ground potential.

3. A plasma processing apparatus as set forth in claim 2,
wherein said first matching device is disposed in the space.

4. A plasma processing apparatus as set forth in claim 1,
wherein said first matching device is electrically connected to said bottom electrode via a non-coaxially structured feeding rod.

5. A plasma processing apparatus as set forth in claim 1,
wherein the first frequency is 13.56 MH_{Z} to 150 MH_{Z}.

6. A plasma processing apparatus as set forth in claim 1,
wherein the second frequency is 0.5 MH_{Z} to 13.56 MH_{Z}.

7. A plasma processing apparatus as set forth in claim 1,
wherein capacitance of said bottom electrode is set to 50 pF or less.

8. A plasma processing apparatus as set forth in claim 1,
wherein the substrate to be processed is etched by the action of the plasma on the substrate to be processed.
